(19) United States
(12) Patent Application Publication
(10) Pub. No.: US 2022/0085207 A1
(43) Pub. Date: Mar. 17, 2022

(54) SEMICONDUCTOR DEVICE AND MANUFACTURING METHOD THEREOF

(71) Applicants: Kabushiki Kaisha Toshiba, Tokyo (JP); Toshiba Electronic Devices & Storage Corporation, Tokyo (JP)

(72) Inventor: Kenji Maeyama, Oita Oita (JP)

(21) Appl. No.: 17/198,414

(22) Filed: Mar. 11, 2021

(30) Foreign Application Priority Data
Sep. 11, 2020 (JP) 2020-153284

(51) Int. Cl. H01L 29/78; H01L 29/66

(52) U.S. Cl. CPC H01L 29/7813; H01L 29/66734

(57) ABSTRACT

According to one embodiment, a semiconductor device includes a first electrode, a first semiconductor region, a second semiconductor region, a third semiconductor region, a gate electrode, an insulating part, and a second electrode. The first semiconductor region is provided on the first electrode and electrically connected to the first electrode. The second semiconductor region is provided on the first semiconductor region. The third semiconductor region is provided on the second semiconductor region. The gate electrode is arranged with one portion of the first semiconductor region, the second semiconductor region, and one portion of the third semiconductor region, via a gate insulating layer. The insulating part is provided on the gate electrode and arranged with another portion of the third semiconductor region. The second electrode is provided on the third semiconductor region and the insulating part. The second electrode is electrically connected to the second and third semiconductor regions.

### CROSS-REFERENCE TO RELATED APPLICATIONS

This application is based upon and claims the benefit of priority from Japanese Patent Application No. 2020-153284, filed on Sep. 11, 2020; the entire contents of which are incorporated herein by reference.

### FIELD

Embodiments described herein relate generally to a semiconductor device and a manufacturing method thereof.

### BACKGROUND

Semiconductor devices such as a Metal-Oxide-Semiconductor Field Effect Transistor (MOSFET) are used in applications such as power conversion. It is desirable that an on-resistance of the semiconductor device is low.

### BRIEF DESCRIPTION OF THE DRAWINGS

FIG. 1 is a perspective cross-sectional view illustrating a semiconductor device according to an embodiment;

FIG. 2 is a cross-sectional view illustrating one portion of the semiconductor device according to the embodiment;

FIGS. 3A and 3B are cross-sectional views illustrating a manufacturing process of the semiconductor device according to the embodiment;

FIGS. 4A and 4B are cross-sectional views illustrating the manufacturing process of the semiconductor device according to the embodiment;

FIGS. 5A and 5B are cross-sectional views illustrating the manufacturing process of the semiconductor device according to the embodiment;

FIGS. 6A and 6B are cross-sectional views illustrating the manufacturing process of the semiconductor device according to the embodiment;

FIG. 7 is a cross-sectional view illustrating one portion of a semiconductor device according to a reference example;

FIGS. 8A and 8B are cross-sectional views illustrating a manufacturing method of the semiconductor device according to the reference example; and

FIG. 9 is a perspective cross-sectional view illustrating a semiconductor device according to a modification of the embodiment.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, an insulating part, and a second electrode. The first semiconductor region is provided on the first electrode and electrically connected to the first electrode. The second semiconductor region is provided on the first semiconductor region. The third semiconductor region is provided on the second semiconductor region. The gate electrode is arranged, in a second direction perpendicular to a first direction directed from the first semiconductor region to the second semiconductor region, with one portion of the first semiconductor region, the second semiconductor region, and one portion of the third semiconductor region, via a gate insulating layer. The insulating part is provided on the gate electrode and arranged in the second direction with another portion of the third semiconductor region. The insulating part includes a first insulating region including silicon and oxygen, and a second insulating region provided on the first insulating region and including silicon and nitrogen. The second electrode is provided on the third semiconductor region and the insulating part. The second electrode is electrically connected to the second semiconductor region and the third semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations n⁺, n− and p⁺, p represent the relative highs and lows of each i impurity concentration. That is, the notation with “+” indicates t hat the impurity concentration is relatively higher than the notation without either “+” or “−”, and the notation with “−” indicates that the impurity concentration is relatively lower than the notation not marked with either “+” or “−”. When each region contains both p-type impurities and n-type impurities, these notations represent the relative high and low of the net impurity concentration after the impurities have compensated for each other.

Also in the embodiments described below, the embodiments may be executed by inverting the p-type and the n-type in the semiconductor regions,

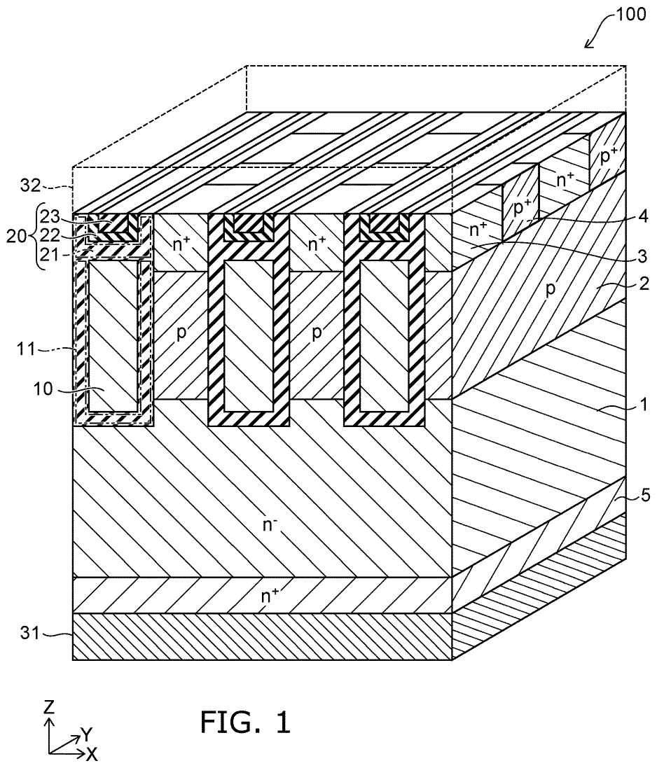

FIG. 1 is a perspective cross-sectional view illustrating a semiconductor device according to an embodiment.

A semiconductor device 100 according to the embodiment a MOSFET. As illustrated in FIG. 1, the semiconductor device 100 according to the embodiment includes an n⁻-type (first conductivity type) drift region 1 (first semiconductor region), a p-type (second conductivity type) base region 2 (second semiconductor region), an n⁺-type source region 3 (third semiconductor region), a p⁺-type contact region 4, an n⁺-type drain region 5, a gate electrode 10, a gate insulating layer 11, an insulating part 20, a drain electrode 31 (first electrode), and a source electrode 32 (second electrode).

The description of the embodiment uses an XYZ orthogonal coordinate system. A direction directed from the n^{'1}-type drift region 1 to the p-type base region 2 is Z-direction (first direction). Two directions that are perpendicular to Z-direction and which are orthogonal to each other are X-direction (second direction) and Y-direction (third direction). Moreover, for description, the direction directed from the n⁻-type drift region 1 to the p-type base region 2 is called “upper”, and its opposite direction is called “lower”. These directions are based on a relative positional relationship between the n⁻-type drift region 1 and the p-type base region 2, and has no relation to the direction of gravity.

The drain electrode 31 is provided on a lower plane of the semiconductor device 100. The n⁺-type drain region 5 is provided on the drain electrode 31, and is electrically connected to the drain electrode 31. The n⁻-type drift region 1 is provided on the n⁺-type drain region 5. The n⁻-type drift region 1 is electrically connected to the drain electrode 31 via the n⁺-type drain region 5. An n-type impurity density in the n⁺-type drain region 5 is higher than an n-type impurity density in the n⁻-type drift region 1.

The p-type base region 2 is provided on the n⁻-type drift region 1. The n⁺-type source region 3 and the p⁺-type contact region 4 are provided on the p-type base region 2. The p⁺-type contact region 4 is arranged in Y-direction with the n⁺-type source region 3. The n-type impurity density in the n⁺-type source region 3 is higher than the n-type impurity density in the n⁻-type drift region 1. A p-type impurity density in the p⁺-type contact region 4 is higher than a p-type impurity density in the p-type base region 2.

The gate electrode 10 is arranged in X-direction with one portion of the n⁻-type drift region 1, the p-type base region 2, one portion of the n⁺-type source region 3, and one portion of the p⁺-type contact region 4, via the gate insulating layer 11. The insulating part 20 is provided on the gate electrode 10. The insulating part 20 is arranged in X-direction with another portion of the n⁺-type source region 3 and another portion of the p⁺-type contact region 4.

The insulating part 20 includes a first insulating region 21, a second insulating region 22, and a third insulating region 23. The first insulating region 21 is provided on the gate electrode 10. The second insulating region 22 is provided on the first insulating region 21. The third insulating region 23 is provided on the second insulating region 22.

The source electrode 32 is provided on the n⁺-type source region 3, the p⁺-type contact region 4, and the insulating part 20, and is electrically connected to the n⁺-type source region 3 and the p⁺-type contact region 4. The p-type base region 2 is electrically connected to the source electrode 32 via the p⁺-type contact region 4. The source electrode 32 is electrically separated from the gate electrode 10 by the insulating part 20.

In the illustrated example, the third insulating region 23 is separated in X-direction from the n⁺-type source region 3 and the p⁺-type contact region 4. The second insulating region 22 is further provided between the n ⁺-type source region 3 and the third insulating region 23, and between the p⁺-type contact region 4 and the third insulating region 23. The first insulating region 21 is further provided between the n⁺-type source region 3 and the second insulating region 22, and between the p⁺-type contact region 4 and the second insulating region 22. For example, the first insulating region 21 is in contact with an upper plane of the gate electrode 10, a side plane of the n⁺-type source region 3, and a side plane of the p⁺-type contact region 4. Upper planes of the first insulating region 21 to the third insulating region 23 are in contact with the source electrode 32.

Described is one example of materials for components of the semiconductor device 100,

The n⁻-type drift region 1, the p-type base region 2, the n⁺-type source region 3, the p⁺-type contact region 4, and the n⁺-type drain region 5 contain, as semiconductor materials, silicon, silicon carbide, gallium nitride, or gallium arsenide. In a case in which silicon is used as the semiconductor material, arsenic, phosphorus, or antimony may be used as the n-type impurity. Boron may be used as the p-type impurity.

The gate electrode 10 contains conductive material such as polysilicon. The gate insulating layer 11 contains silicon and oxygen. The drain electrode 31 and the source electrode 32 contain at least one metal selected from the group consisting of titanium, tungsten, and aluminum.

The first insulating region 21 and the third insulating region 23 contain silicon and oxygen. The second insulating region 22 contains silicon and nitrogen. For example, the first insulating region 21 and the third insulating region 23 contains silicon oxide. The second insulating region 22 contains silicon nitride. Therefore, a relative permittivity of the second insulating region 22 is higher than a relative permittivity of each of the first insulating region 21 and the third insulating region 23. The first insulating region 21 and the third insulating region 23 may further contain nitrogen. In this case, nitrogen concentrations in the first insulating region 21 and the third insulating region 23 are lower than the nitrogen concentration in the second insulating region 22.

For example, a plurality of the p-type base region 2, the gate electrode 10, and the insulating part 20 are provided in X-direction. The p-type base regions 2, the gate electrodes 10, and the insulating parts 20 extend in Y-direction. The plurality of p-type base regions 2 are provided alternately in X-direction with the plurality of gate electrodes 10. A plurality of the n⁺-type source region 3 and the p⁺-type contact region 4 are provided in X- and Y-directions. Between adjacent insulating parts 20 in X-direction, the plurality of the n⁺-type source regions 3 and the plurality of the p⁺-type contact regions 4 are provided alternately in Y-direction.

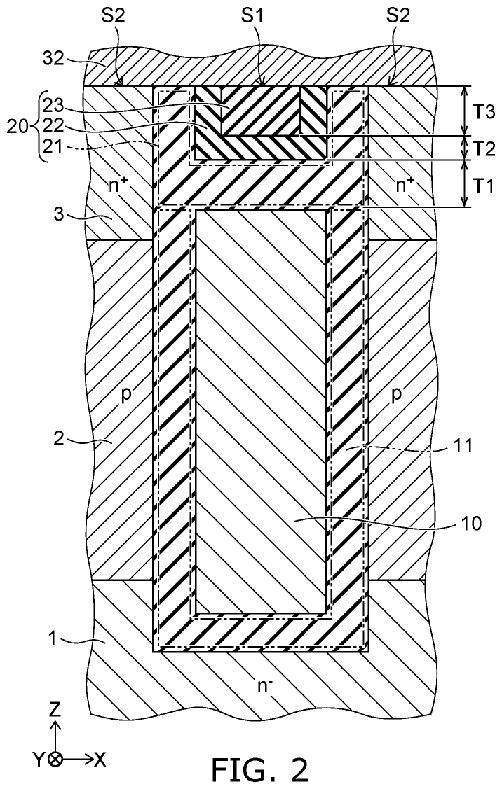

FIG. 2 is a cross-sectional view illustrating a portion of the semiconductor device according to the embodiment.

As illustrated in FIGS. 1 and 2, one portion of the first insulating region 21 is positioned in Z-direction between the gate electrode 10 and the third insulating region 23. One portion of the second insulating region 22 is positioned in Z-direction between the gate electrode 10 and the third insulating region 23.

A thickness T1 in Z-direction of the first insulating region 21, a thickness T2 in Z-direction of the second insulating region 22, and a thickness T3 in Z-direction of the third insulating region 23 illustrated in FIG, 2 are arbitrary. For example, the thickness T2 is less than each of the thicknesses T1 and T3. The thickness T1 corresponds to a length of the one portion in Z-direction of the first insulating region 21. The thickness T2 corresponds to a length of the one portion in Z-direction of the second insulating region 22.

An upper plane S1 of the insulating part 20 is arranged in X-direction with an upper plane S2 of the n⁺-type source region 3 and an upper plane of the p⁺-type contact region 4. For example, this is on the basis that the upper plane S1 of the insulating part 20, the upper plane S2 of the n⁺-type source region 3, and the p⁺-type contact region 4 are processed in a same single flattening process.

Operations of the semiconductor device 100 will be described.

In a state in which a voltage positive against the source electrode 32 is applied on the drain electrode 31, a voltage higher than a threshold is applied to the gate electrode 10. A channel (inversion layer) is formed on the p-type base region 2. Electrons flow to the drain electrode 31 via the channel and the n⁻-type drift region 1. This causes the semiconductor device 100 to be in an on-state. Thereafter, when the voltage applied on the gate electrode 10 becomes lower than the threshold, the channel in the p-type base region 2 disappears, thus causing the semiconductor device 100 to be in an off-state.

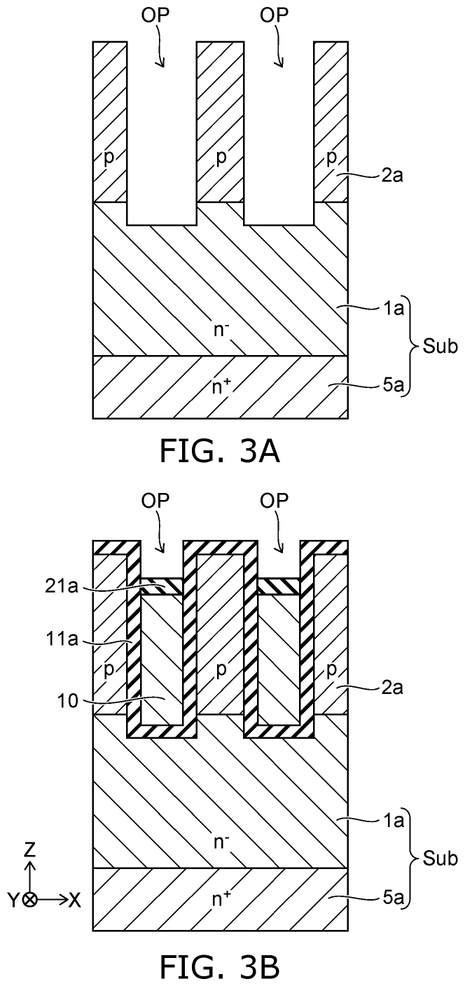

FIGS. 3A to 6B are cross-sectional views illustrating a manufacturing process of the semiconductor device according to the embodiment.

One example of a manufacturing method of the semiconductor device 100 of the embodiment will be described. First, a substrate Sub including an n⁺-type semiconductor layer 5a and an n⁻-type semiconductor layer 1a is prepared. The n⁻-type semiconductor layer 1a is provided on the n⁺-type semiconductor layer 5a. The p-type impurity is ion-implanted on an upper plane of the substrate Sub, to form a p-type semiconductor region 2a. As illustrated in FIG. 3A, openings OP are formed on the upper plane of the substrate Sub by reactive ion etching (RIE). A plurality of the openings OP are formed in the X-direction, and each of the openings OP extend in the Y-direction. The openings OP are arranged in X-direction with one portion of the n⁻-type semiconductor layer is and the p-type semiconductor region 2a. One portion of a surface of the n⁻-type semiconductor layer 1a and a side plane of the p-type semiconductor region 2a constitute side walls of the openings OP.

Thermal oxidation is performed to the substrate Sub to form an insulating layer 11a (first insulating layer). The insulating layer 11a is formed along inner planes of each opening OP and an upper plane of the p-type semiconductor region 2a . By chemical vapor deposition (CVD), a conductive layer that buries a plurality of the openings OP is formed on the insulating layer 11a. By wet etching or chemical dry etching (CDE), an upper plane of the conductive layer is retracted until the upper plane of the conductive layer is positioned lower than the upper plane of the p-type semiconductor region 2a . This divides the conductive layer into a plural number, thus forming the gate electrode 10 inside each of the openings OP. As illustrated in FIG. 3B, an insulating layer 21a (second insulating layer) is formed on an upper plane of each of the gate electrodes 10, by thermal oxidation.

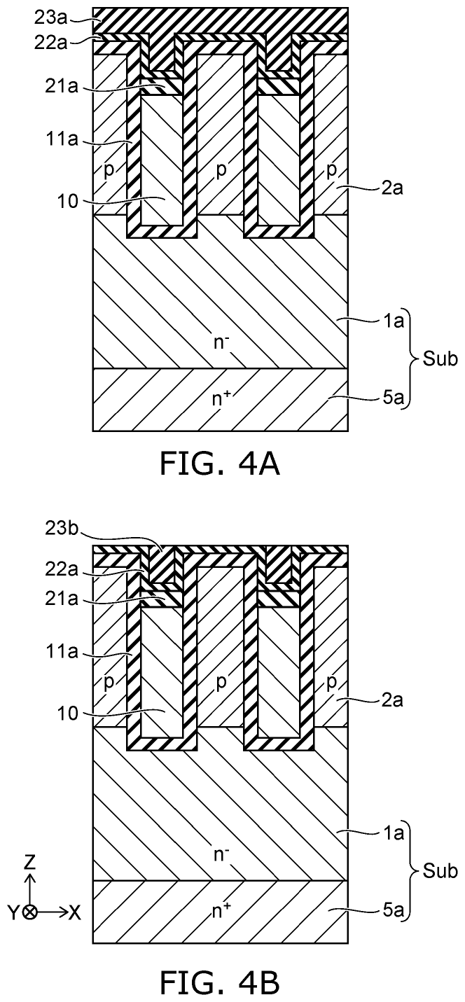

By CVD, an insulating layer 22a (third insulating layer) is formed along a surface of the insulating layer 11a and surfaces of a plurality of the insulating layers 21a . The insulating layer 22a contains silicon and nitrogen. As illustrated in FIG. 4A, by CVD, an insulating layer 23a (fourth insulating layer) that buries a plurality of the openings OP is formed on the insulating layer 22a . The insulating layer 23a contains silicon and oxygen.

By chemical mechanical polishing (CMP), an upper plane of the insulating layer 23a is reduced until the upper plane of the insulating layer 23a reaches the same position as the upper plane of the insulating layer 22a . This divides the insulating layer 23 into a plural number, thus forming an insulating layer 23b above each of the insulating layers 21a . The insulating layer 22a includes materials different from those of the insulating layer 23a ; hence, the insulating layer 22a may be used as a stopper.

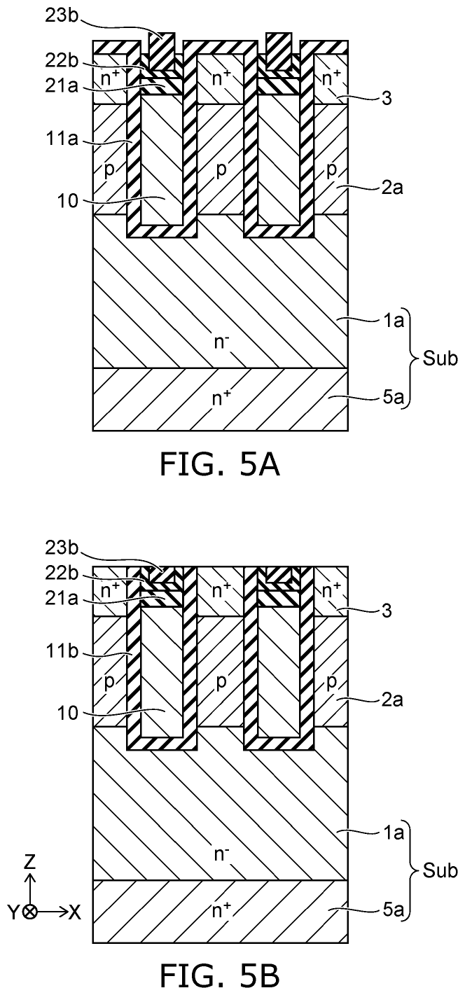

By wet etching, the upper plane of the insulating layer 22a is retracted to lower than the upper plane of the insulating layer 11a . This divides the insulating layer 22a into a plural number, thus forming the insulating layers 22b between the insulating layers 21a and 23b . The n-type impurity is ion-implanted on one portion of the upper plane of the p-type semiconductor region 2a , to form a plurality of the n⁺-type source regions 3 as illustrated in FIG. 5A, The p-type impurity is ion-implanted in another portion of the upper plane of the p-type semiconductor region 2a , to form a plurality of the p⁺-type contact region 4.

Until a plurality of the n⁺-type source regions 3 and a plurality of the p⁺-type contact regions 4 are exposed, one portion of each of the insulating layer 11a , the insulating layer 22b , and the insulating layer 23b are removed by CMP. This divides the insulating layer 11a into a plural number, to form the insulating layer 11b as illustrated in FIG. 5B. Moreover, as a result of flattening by CMP, the upper planes of the n⁺-type source region 3, the p⁺-type contact region 4, the insulating layer 11b, the insulating layer 21a , and the insulating layer 22b are arranged in X-direction with each other,

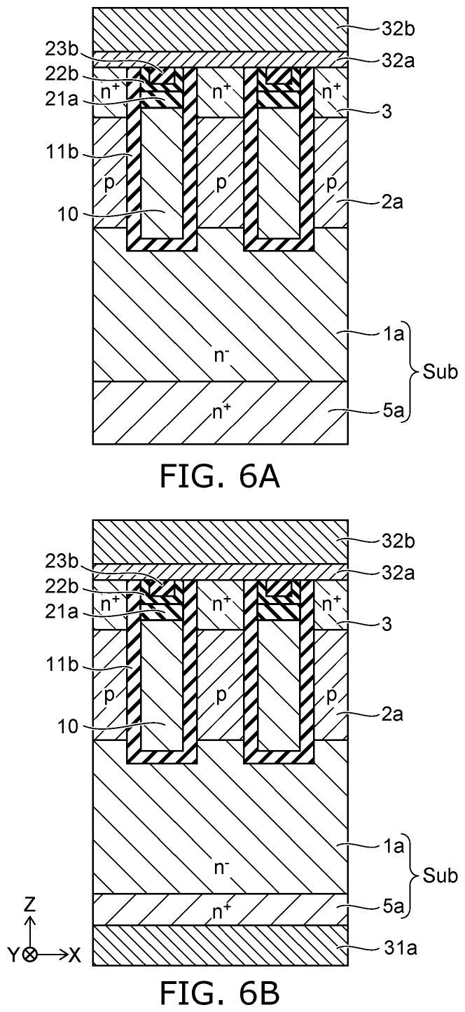

A metal layer 32a is formed on the n⁺-type source region 3, the p⁺-type contact region 4, and the insulating layers 11b , 21a , 22b , and 23b by sputtering. As illustrated in FIG. 6A, a metal layer 32b is formed on the metal layer 32a by sputtering. The metal layer 32a contains titanium, titanium nitride, or tungsten. The metal layer 32b contains aluminum.

A lower plane of the n⁺-type semiconductor layer 5a is abraded until the n⁺-type semiconductor layer 5a reaches a predetermined thickness. As illustrated in FIG. 6B, a metal layer 31a is formed on the lower plane of the n⁺-type semiconductor layer 5a by sputtering. The metal layer 31a contains aluminum. The semiconductor device 100 according to the embodiment is manufactured as the above.

The n⁻-type semiconductor layer 1a excluding the p-type semiconductor region 2a , the n⁺-type source region 3, and the p⁺-type contact region 4 corresponds to the n⁻-type drift region 1 illustrated in FIG. 1. The p-type semiconductor region 2a excluding the n⁺-type source region 3 and the p⁺-type contact region 4 corresponds to the p-type base region 2. The n⁺-type semiconductor layer 5a after being abraded corresponds to the n⁺-type drain region 5. One portion of the insulating layer 11b corresponds to the gate insulating layer 11. Another one portion of the insulating layer 11b and the insulating layer 21 correspond to the first insulating region 21. The insulating layer 22b corresponds to the second insulating region 22. The insulating layer 23b corresponds to the third insulating region 23. The metal layer 31a corresponds to the drain electrode 31. The metal layers 32a and 32b correspond to the source electrode 32.

Effects by the semiconductor device 100 according to the embodiment will be described.

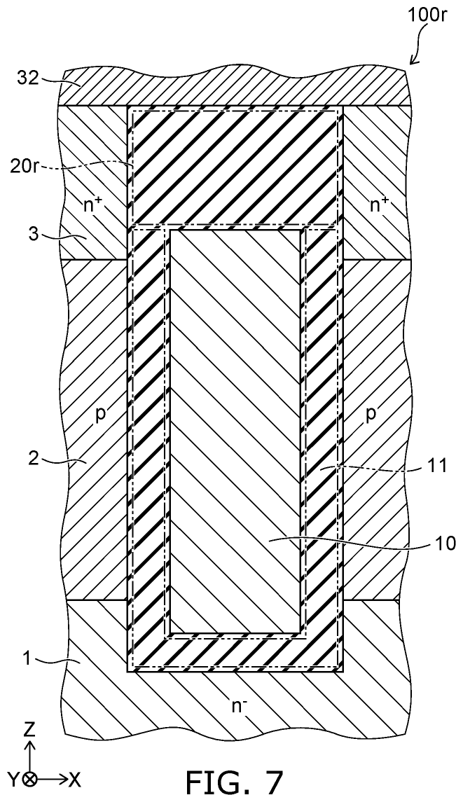

FIG. 7 is a cross-sectional view illustrating one portion of the semiconductor device according to a reference example.

In a semiconductor device 100r according to the reference example illustrated in FIG. 7, an insulating part 20r is provided on the gate electrode 10. The insulating part 20r does not include the second insulating region 22. The relative permittivity of the insulating part 20r is uniform across Z-direction. The insulating part 20r contains silicon and oxygen.

When the semiconductor devices 100 and 100r are in the on-state, a voltage is applied on the gate electrode 10 with respect to the source electrode 32. An electric field generates on the insulating parts 20 and 20r , provided between the gate electrode 10 and the source electrode 32. The thickness of the insulating layers 20 and 20r each in Z-direction is designed to cause no electrical breakdown by the electric field.

Comparing the semiconductor devices 100 and 100r , in the semiconductor device 100, the insulating part 20 includes the second insulating region 22. In the semiconductor device 100, the relative permittivity of the second insulating region 22 is higher than the relative permittivities of the first insulating region 21 and the third insulating region 23. The relative permittivity of the second insulating region 22 is higher than the relative permittivity of the insulating part 20r in the semiconductor device 100r . Therefore, an electric field strength that electrical breakdown occurs in the insulating part 20 (maximum electric field strength) is higher than the maximum electric field strength in the insulating part 20r . In a case in which a same voltage is applied on the gate electrode 10 in the semiconductor devices 100 and 100r , the thickness in Z-direction of the insulating part 20 may be made less than the thickness in Z-direction of the insulating part 20r . When the thickness in Z-direction of the insulating part 20 becomes less, the thickness in Z-direction of the n⁺-type source region 3 may be made less, for example. When the thickness of the n⁺-type source region 3 becomes less, an electrical resistance of the n⁺-type source region 3 may be reduced. As a result, the on-resistance of the semiconductor device 100 can be reduced.

Moreover; in the insulating region 20, the first insulating region 21 is provided between the gate electrode 10 and the second insulating region 22. The relative permittivity of the first insulating region 21 is lower than the relative permittivity of the second insulating region 22. By providing the first insulating region 21, it is possible to relax the concentration of electric field around a corner of an upper portion of the gate electrode 10. This enables to reduce the possibility that a breakdown occurs in the semiconductor device 100 due to electric field concentration.

The first insulating region 21 to the third insulating region 23 may be provided flat along the X-Y planes. Preferably, as illustrated in FIGS. 1 and 2, the third insulating region 23 is separated in X-direction from the n⁺-type source region 3. The second insulating region 22 is further provided in X-direction between the n⁺-type source region 3 and the third insulating region 23. The first insulating region 21 is further provided in X-direction between the n⁺-type source region 3 and the second insulating region 22.

The second insulating region 22 contains silicon and nitrogen, and is chemically stable than the first insulating region 21 and the third insulating region 23. According to the configuration illustrated in FIGS. 1 and 2, it is possible to hold down movement of movable ions contained in the third insulating region 23. For example, it is possible to hold down the movable ions from moving to the gate insulating layer 11 by the electric field generated on the insulating part 20. The movable ions are hydrogen, sodium or the like. When the movable ions move to the gate insulating layer 11, the movable ions move within the gate insulating layer 11 in response to a voltage application to the gate electrode 10. As a result, the threshold of the semiconductor layer 100 fluctuates, which may cause an increase in channel leak. By holding down the movement of the movable ions to the gate insulating layer 11, the fluctuation in the threshold of the semiconductor device 100 can be held down, hence allowing for improvement in the reliability of the semiconductor device 100.

Advantages of the manufacturing method according to the embodiment are described.

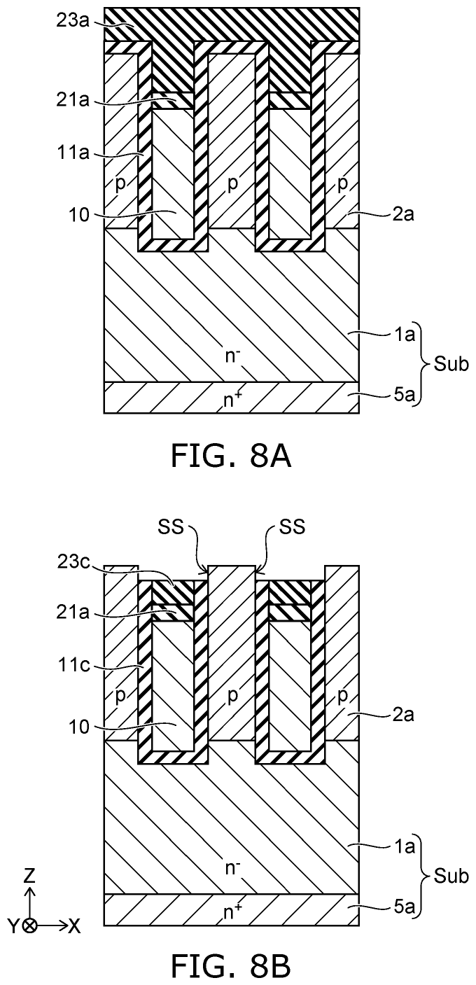

FIGS. 8A and 8B are cross-sectional views illustrating a manufacturing method of the semiconductor device according to a reference example.

In the manufacture of the semiconductor device 100r according to the reference example, first, processes that are the same as the processes illustrated in FIGS. 3A and 3B are performed. Thereafter, as illustrated in FIG. 8A, the insulating layer 23a is formed without forming the insulating layer 22a . One portion of each of the insulating layers 11a and 23a are removed by wet etching or CDE, to expose the p-type semiconductor region 2a . This forms the insulating layers 11c and 23c around respective gate electrodes 10, as illustrated in FIG. 8B. Thereafter, the n⁺-type source region 3 and the p⁺-type contact region 4 are formed on an upper plane of the p-type semiconductor region 2a.

In the manufacturing method according to the reference example, the insulating layers 11a and 23a are overetched with respect to the upper plane of the p-type semiconductor region 2a , to securely expose the p-type semiconductor region 2a . By the amount that the thickness in Z-direction of the insulating layers 11a and 23a are overetched, the thickness in Z-direction of the n⁺-type source region 3 increases. The greater the thickness of the n⁺-type source region 3, the more the electrical resistance of the n⁺-type source region 3 increases; this causes an increase in the on-resistance of the semiconductor device 100r.

In the manufacturing method according to the embodiment, a structural body including the n⁻-type semiconductor layer 1a, the p-type semiconductor region 2a , the insulating layer 11a , the gate electrode 10, and the insulating layer 21a is produced, as illustrated in FIG. 3B. As illustrated in FIG. 4A, the insulating layers 22a and 23a are formed on the insulating layer 11a and the insulating layer 21a . Thereafter, one portion of the insulating layer 23a is removed, as illustrated in FIG. 4B. At this time, the insulating layer 22a may be used as a stopper. Therefore, it is possible to hold down the overetching of the insulating layer 23a with respect to the upper plane of the p-type semiconductor region 2a . Accordingly, the thickness of the n⁺-type source region 3 in Z-direction may be made less. As a result, the on-resistance of the semiconductor device 100 to be manufactured may be reduced.

Moreover, in the manufacturing method according to the reference example, when the n⁺-type source region 3 is formed, a side plane SS in an upper portion of the p-type semiconductor region 2a is exposed. The n-type impurity is ion-implanted also from the exposed side plane SS. A length in Z-direction of the side plane SS corresponds to the thickness in Z-direction of the insulating layer 11a to be overetched. The thickness of the insulating layer 11a to be over-etched varies. Therefore, the length in Z-direction of the side plane SS will also vary. If the length of the side plane SS varies, the thickness in Z-direction of the n⁺-type source region 3 will vary. As a result, the thickness in Z-direction of the p-type semiconductor region 2a will vary, thus causing a variation in the electrical resistance of the channel.

In the manufacturing method according to the embodiment, the n⁺-type source region 3 is formed in a state in which the surface of the p-type semiconductor region 2a is covered by the insulating layer 22a , as illustrated in FIG. 4B. Therefore, compared to the manufacturing method according to the reference example, it is possible to reduce the variation in the amount of impurities implanted into the p-type semiconductor region 2a . As a result, the variation in electrical resistance of the channel can be reduced, thus allowing for improving the reliability of the semiconductor device 100.

When forming the n⁺-type source region 3, the n-type impurity may be implanted into the p-type semiconductor region 2a through a gap between the insulating layers 11a and 23a illustrated in FIG. 5A. As a result, the n⁺-type source region 3 is formed deeply in a localized manner in the vicinity of the insulating layer 11a . Namely, the thickness in Z-direction of the p-type semiconductor region 2a becomes locally less, and a channel length becomes short. The variation in channel length serves as a cause for the variation in the electrical resistance of the semiconductor device 100.

In the semiconductor device 100, the thickness T2 in Z-direction of the second insulating region 22 is preferably less than each of the thickness T1 in Z-direction of the first insulating region 21 and the thickness T3 in Z-direction of the third insulating region 23, as illustrated in FIG. 2. The less the thickness T2, the less the insulating layer 22b corresponding to the second insulating region 22 in the process illustrated in FIG. 5A. Namely, above the insulating layer 22b , the gap in X-direction between the insulating layers 11a and 23b becomes small. When forming the n⁺-type source region 3, it is possible to hold down the implantation of the n-type impurity to the p-type semiconductor region 2a through the gap between the insulating layers 11a and 23b . As a result, it is possible to reduce the variation in thickness in Z-direction of the p-type semiconductor region 2a , and reduce the variation in the electrical resistance of the semiconductor device 100. The reliability of the semiconductor device 100 can be improved.

### (Modification)

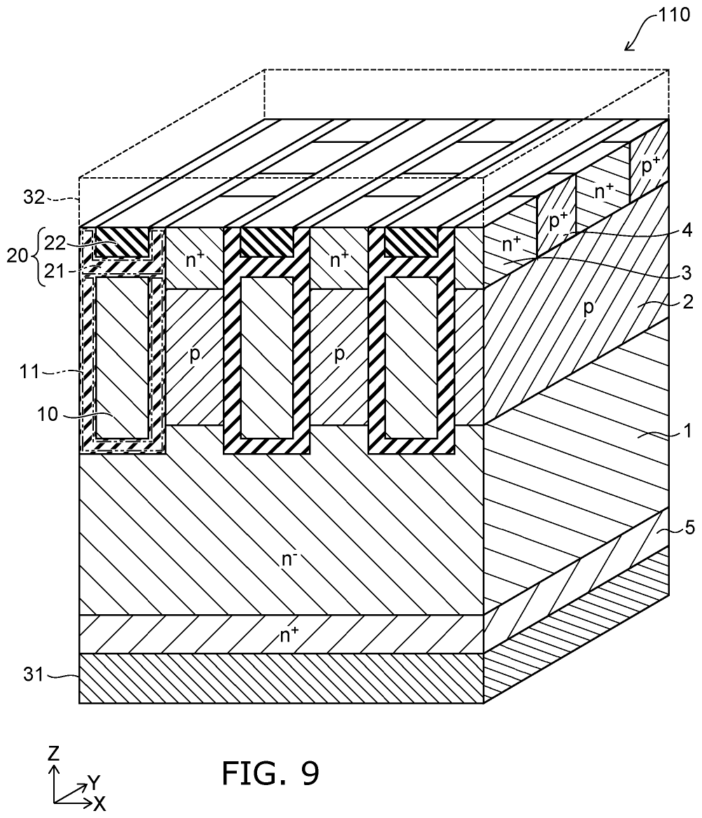

FIG. 9 is a perspective cross-sectional view illustrating a semiconductor device according to a modification of the embodiment.

In a semiconductor device 110 illustrated in FIG. 9, the insulating part 20 includes no third insulating region 23. The second insulating region 22 is further provided in the region in which the third insulating region 23 is provided in the semiconductor device 100.

According to the semiconductor device 110, the second insulating region 22 is provided in a broader region as compared to the semiconductor device 100. This allows for further improving the maximum electric field strength of the insulating part 20. As a result, the thickness of the n⁺-type source region 3 may be made more less, thus allowing for reducing the on-resistance of the semiconductor device 100.

On the other hand, in the case in which the insulating part 20 includes the third insulating region 23, when forming the n⁺-type source region 3 in the process illustrated in FIG. 5A, it is possible to block, by the insulating layer 23b , the n-type impurity that is injected into the p-type semiconductor region 2a in an inclined manner through the upper of the insulating layer 22b . As a result, it is possible to reduce the variation in thickness in Z-direction of the p-type semiconductor region 2a , and can reduce the variation in the electrical resistance of the channel. The reliability of the semiconductor device 100 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. The above embodiments can be practiced in combination with each other.

What is claimed is:

1. A semiconductor device comprising:
a first electrode;
a first semiconductor region of a first conductivity type provided on the first electrode and electrically connected to the first electrode;
a second semiconductor region of a second conductivity type provided on the first semiconductor region;
a third semiconductor region of the first conductivity type provided on the second semiconductor region;
a gate electrode arranged, in a second direction perpendicular to a first direction directed from the first semiconductor region to the second semiconductor region, with one portion of the first semiconductor region, the second semiconductor region, and one portion of the third semiconductor region, via a gate insulating layer;
an insulating part provided on the gate electrode and arranged in the second direction with another portion of the third semiconductor region, the insulating part including:
a first insulating region including silicon and oxygen, and
a second insulating region provided on the first insulating region and including silicon and nitrogen; and
a second electrode provided on the third semiconductor region and the insulating part, the second electrode being electrically connected to the second semiconductor region and the third semiconductor region.

2. The device according to claim 1, wherein
the insulating part further includes a third insulating region provided on the second insulating region,
the third insulating region includes silicon and oxygen.

3. The device according to claim 2, wherein
the third insulating region is separated in the second direction from the third semiconductor region,
the second insulating region is further provided in the second direction between the third semiconductor region and the third insulating region, and
the first insulating region is further provided in the second direction between the third semiconductor region and the second insulating region.

4. The device according to claim 1, wherein a thickness in the first direction of the second insulating region is less than a thickness in the first direction of each of the first insulating region and the third insulating region.

5. The device according to claim 1, wherein an upper plane of the insulating part is arranged in the second direction with an upper plane of the third semiconductor region.

6. A manufacturing method of a semiconductor device, comprising:
forming a third insulating layer including silicon and nitrogen along a surface of a first insulating layer and an upper plane of a second insulating layer of a structural body, the structural body including:
a semiconductor layer of a first conductivity type;
a semiconductor region of a second conductivity type provided on the semiconductor layer;
an opening arranged, in a second direction perpendicular to a first direction from the semiconductor layer to the semiconductor region, with one portion of the semiconductor layer and the semiconductor region;
the first insulating layer provided along an inner plane of the opening and an upper plane of the semiconductor region;
a gate electrode provided inner of the opening on the first insulating layer; and
the second insulating layer provided on the gate electrode,
forming a fourth insulating layer including silicon and oxygen and burying the opening; and
removing one portion of the fourth insulating layer by using the third insulating layer as a stopper.

7. The method according to claim 6, wherein
after removing the one portion of the fourth insulating layer, ion-implanting an impurity of the first conductivity type in an upper portion of the semiconductor region, to form a separate semiconductor region of the first conductivity type.
